(19) United States
(12) Patent Application Publication
(10) Pub. No.: US 2025/0321255 A1
(43) Pub. Date: Oct. 16, 2025

(54) ELECTRONIC CIRCUIT FOR EMBEDDED IMPEDANCE CHECKING AND IMPEDANCE CHECKING METHOD

(71) Applicant: Schaeffler Technologies AG & Co. KG, Herzogenaurach (DE)

(72) Inventors: Nathalie COMBET, CUGNAUX (FR); Jean CANNAVO, Toulouse (FR)

(21) Appl. No.: 19/096,064

(22) Filed: Mar. 31, 2025

(30) Foreign Application Priority Data
Apr. 12, 2024 (FR) 2403790

(51) Int. Cl. G01R 27/02

(52) U.S. Cl. CPC G01R 27/02

(57) ABSTRACT

The present invention relates to an electronic circuit (10) having a first component (12), a second component (14) and an electronic bus (16) capable of setting up a communication between the first component (12) and the second component (14),
the first component (12) comprising:
   transmitting means (20) for transmitting a voltage, and
   measuring means (22) for measuring a voltage;
the second component (14) having:
   a reference impedance (26), and
   switching means (28),
the electronic circuit (10) further having a nominal state, a test state in which:
   the transmitting means (20) are configured to send a predefined voltage signal (30) on the bus,
   the switching means (28) are configured in the connected state, and
   the measuring means (22) are configured to measure a reflected voltage signal (32) coming from the bus.

### TECHNICAL FIELD OF THE INVENTION

The present invention relates to the field of communication bus impedance checking within electronic circuits.

The invention relates more particularly to an electronic circuit for embedded impedance checking and to an impedance checking method in such an electronic circuit.

### TECHNICAL BACKGROUND

Many electronic circuits have at least two components that exchange information via a communication bus. Some fast busses need to be routed with controlled impedance.

When designing such an electronic circuit, the impedance of the bus is calculated theoretically or in a simulated manner using a computer-aided design (CAD) tool.

The electronic circuit is then manufactured with tolerances that are generally of the order of 10%.

At the end of the manufacturing process, it is necessary to check that the impedance of the bus adheres to the specifications and is within the tolerance range. The current method of measuring the impedance of a bus within a printed circuit, in particular, is very long and tedious. The method requires a bare printed circuit and cannot be performed on all printed circuits that come out of production. Therefore, the impedance measurement is only representative of one manufacturing batch of the printed circuit.

### SUMMARY OF THE INVENTION

The invention proposes an electronic circuit having a first component, a second component and an electronic bus capable of setting up a communication between the first component and the second component,
the first component comprising:
   transmitting means for transmitting a voltage, and
   measuring means for measuring a voltage;
the second component having:
   a reference impedance equal to the theoretical impedance of the bus, and
   switching means having a connected state in which the reference impedance is connected to the bus and a disconnected state in which the reference impedance is disconnected from the bus,
the electronic circuit further having a nominal state, a test state in which:
   the transmitting means are configured to send a predefined voltage signal on the bus,
   the switching means are configured in the connected state, and
   the measuring means are configured to measure a reflected voltage signal coming from the bus.

According to other features of the invention:
the first component is a microcontroller;
the second component is a transceiver or a network switch;
the measuring means have an analog-to-digital converter or analog comparison means.

The invention also relates to an impedance checking method implemented in an electronic circuit having a first component, a second component and an electronic bus capable of setting up a communication between the first component and the second component,
the first component comprising:
   transmitting means for transmitting a voltage, and
   measuring means for measuring a voltage;
the second component having:
   a reference impedance equal to the theoretical impedance of the bus, and
   switching means having a connected state in which the reference impedance is connected to the bus and a disconnected state in which the reference impedance is disconnected from the bus,
the method comprising the following steps:
   E1: within the second component, putting the switching means into the connected state so as to connect the reference impedance to the bus;
   E2: sending a voltage signal on the bus using the transmitting means of the first component,
   E3: measuring, using the measuring means of the first component, a reflected voltage signal coming from the bus.

According to other features of the invention:
when the first component further has a memory, the method further comprises a step E4 of storing the measurement in the memory;
the method further comprises step E5: analyzing the measurement carried out in step E3 according to at least one predefined criterion in order to determine whether or not the impedance of the bus is acceptable;
the predefined criterion has at least one voltage threshold value for the measurement;
in step E2, the voltage signal sent is made up of a long voltage pulse followed by a short voltage pulse;
in step E2, the voltage signal sent is made up of multiple short voltage pulses having multiple voltage rise gradient steepnesses and the method further comprises a step E6: determining the maximum operating frequency of the bus according to the steepness beyond which the impedance is degraded;
the method is implemented in an automated manner by an embedded system within the electronic circuit;
when the analysis carried out in step E5 has identified that the impedance of the bus is lower than the theoretical impedance of the bus to within a tolerance range, the method further comprises step E7: connecting an additional impedance in series within the first component;
the method further comprises step E8: within the second component, connecting a variable impedance in parallel with the reference resistor and matching the variable impedance to cancel the reflected wave on the bus.

### BRIEF DESCRIPTION OF THE FIGURES

Further features and advantages of the invention will become apparent from the detailed description that follows, which is understood with reference to the attached drawings, in which:

FIG. 1 is a schematic representation of an electronic circuit according to a first embodiment of the invention;

FIG. 2 is a graph showing the voltage signal measured when a voltage square-wave is sent on the bus of the electronic circuit of FIG. 1;

FIG. 3 is a graph showing the voltage signal measured when a voltage pulse is sent on the bus of the electronic circuit of FIG. 1;

FIG. 4 is a schematic representation of a printed circuit according to a second embodiment of the invention showing vias on the bus of the printed circuit;

FIG. 5 is a graph showing the voltage signal measured when a voltage square-wave is sent on the bus of the printed circuit of FIG. 4;

FIG. 6 is a graph showing a voltage signal transmitted on a bus of an electronic circuit according to a third embodiment of the invention, the transmitted signal being made up of a chain of voltage pulses having edges with different rise times.

### DETAILED DESCRIPTION OF THE INVENTION

For the description of the invention and the understanding of the claims, the vertical, longitudinal and transverse orientations will be adopted nonlimitingly, and without limiting reference to the gravitational field of the earth, according to the frame of reference V, L, T indicated in the figures, in which the longitudinal axis L and transverse axis T extend in a horizontal plane. By convention, the longitudinal axis Lis oriented from the rear forwards.

In the description that follows, elements that are identical, similar or analogous will be denoted by the same reference numerals.

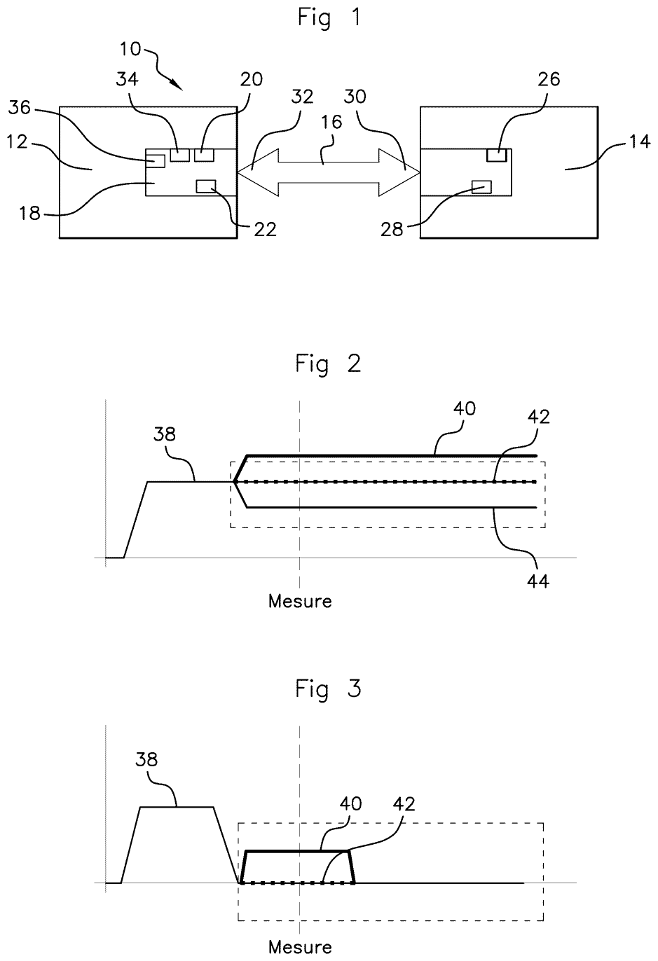

FIG. 1 illustrates an electronic circuit 10 according to one embodiment of the invention. The electronic circuit 10 has a first component 12, a second component 14 and an electronic bus 16 capable of setting up a communication between the first component 12 and the second component 14.

The first component 12 comprises a first functional assembly 18 that is activated in a test mode. The first functional assembly 18 of the first component 12 has:
transmitting means 20 for transmitting a voltage, and
measuring means 22 for measuring a voltage.

The second component 14 has a second functional assembly 24 that is activated in the test mode. The second functional assembly 24 of the second component 14 has:
a reference impedance 26 equal to the theoretical impedance of the bus 16, and
switching means 28 having a connected state in which the reference impedance 26 is connected to the bus 16 and a disconnected state in which the reference impedance 26 is disconnected from the bus 16.

When the first functional assembly 18 and the second functional assembly 24 are activated, the electronic circuit is said to be in the test state.

In the test state:
the transmitting means 20 are configured to send a predefined voltage signal 30 on the bus 16,
the switching means 28 are configured in the connected state, and
the measuring means 22 are configured to measure a reflected voltage signal 32 coming from the bus 16.

The first component 12 can be, for example:
a microcontroller,
a microprocessor,
an Ethernet network switch,
an expansion card such as a graphics card,
a solid-state drive (SSD), that is to say a disk storing information in flash memory,
a hard drive, or
a network card having, for example, an expansion bus according to the PCI Express, Peripheral Component Interconnect Express, standard.

The second component 14 can be, for example:
a transceiver, or
an Ethernet network switch.

The measuring means 22 have, for example:
an analog-to-digital converter, or
analog comparison means.

In order to check the impedance of the bus 16 within the electronic circuit 10, the test mode is programmed into a logic unit 34 of the electronic circuit 10. The logic unit 34 is, for example, included by the first functional assembly 18 of the first component 12. The logic unit 34 can be coupled to a memory 36.

Thus, the impedance checking method is embedded in an electronic chip and can be triggered by means of the test mode at any time by an operator, or in a programmed or automatable manner, and automatically provide test results in a few milliseconds.

The impedance checking method of the invention is based on the application of reflectometry principles to the electronic circuit 10 in order to establish the following relationship between the reference impedance 26 and the impedance of the bus 16:

$$p = \frac{( Z b u s - Z r e f )}{( Z b u s + Z r e f )} \qquad [ Math . 1 ]$$

where:
p is the reflection coefficient (ratio of the reflected wave to the transmitted wave),
Zref is the value of the reference impedance 26,
Zbus is the value of the impedance of the bus 16.

According to the above formula, the reflection coefficient p is zero, that is to say the reflected wave is zero, when the value of the impedance of the bus 16 is equal to the value of the reference impedance 26 (Zbus=Zref).

If the value Zref of the reference impedance 26 is chosen to be equal to the desired value for the impedance Zbus of the bus 16, the method of the invention therefore consists in checking that the reflected voltage signal 32 is zero.

The test mode comprises implementing an impedance checking method comprising the following steps:
E1: putting the switching means 28 into the connected state so as to connect the reference impedance 26 to the bus 16;
E2: sending a voltage signal 30 on the bus 16 using the transmitting means 20 of the first component 12,
E3: measuring, using the measuring means 22 of the first component 12, a reflected voltage signal 32 coming from the bus 16,
E4: storing the measurement in the memory 36,
E5: analyzing the measurement carried out in step E3 according to at least one predefined criterion in order to determine whether or not the impedance of the bus 16 is acceptable.

Step E1 corresponds to putting the electronic circuit 10 into the test state.

Steps E2 and E3 are carried out in the manner of a time domain reflectometer (TDR). In step E2, the transmitting means 20 transmit a pulse with a very fast rise time on the bus 16. The edge, that is to say the rise time of the pulse, depends on the functional frequency of the bus 16.

The measurement of the reflected voltage signal 32 can be used to calculate the reflection coefficient of the line (ratio of the reflected wave to the transmitted wave). Using the formula math.1, it is possible to deduce the impedance of the bus 16 from the values of the reference impedance 26 and the reflection coefficient p.

If the bus 16 is impedance-matched, that is to say if the bus 16 has an impedance equal to the reference impedance 26, the transmitted pulse will be entirely absorbed at the end of the line and no signal will be reflected towards the measuring means 22.

The expected target value for the impedance of the bus is, for example, 50 Ω.

In the event of an impedance discontinuity, part of the incident voltage signal 30 will be sent back on the bus to the measuring means 22.

If the impedance of the bus 16 is lower than the reference impedance 26, then a reflection that opposes the original pulse is generated. On the other hand, if the impedance of the bus 16 is higher than the reference impedance 26, then a reflection that reinforces the original pulse is generated.

FIG. 2 shows the signal measured by the measuring means 22 when the transmitting means 20 send a voltage square-wave. The measurement for checking the impedance is taken after a certain fixed time indicated by the vertical dotted line and corresponding to twice the propagation time of the electric wave on the bus 16.

The signal shown in FIG. 2 represents:
a transmitted wave 38,
a first measured wave 40 when the impedance of the bus 16 is higher than the reference impedance 26,
a second measured wave 42 when the impedance of the bus 16 is equal to the reference impedance 26,
a third measured wave 44 when the impedance of the bus 16 is lower than the reference impedance 26.

If the square-wave is transmitted with a full-scale voltage by the transmitting means 20, all the voltages or discontinuities above the full-scale voltage, and in particular the first measured wave 40, can be clipped by the measuring means 22. In this case, it is not possible to distinguish between the following two situations:
the impedance of the bus 16 is higher than the reference impedance 26,
the impedance of the bus 16 is equal to the reference impedance 26.

FIG. 3 shows the signal measured by the measuring means 22 when the transmitting means 20 send a short voltage pulse. In particular, the voltage pulse has a duration less than twice the propagation time of the electric wave on the bus 16 so that the transmitted wave does not overlap the reflected wave. It is then possible to distinguish between the following two situations that were confused in the example of FIG. 2:
the impedance of the bus 16 is higher than the reference impedance 26: this is the case when the first measured wave 40 has a positive voltage value slightly lower than the transmitted voltage,
the impedance of the bus 16 is equal to the reference impedance 26: this is the case when the second measured wave 42 has a zero voltage value.

However, in the example of FIG. 3, it is not possible to distinguish between the following two situations, which both correspond to a measured wave of zero voltage:
the impedance of the bus 16 is lower than the reference impedance 26,
the impedance of the bus 16 is equal to the reference impedance 26.

To allow the impedance of the bus 16 to be checked under all circumstances, that is to say when:
the impedance of the bus 16 is lower than the reference impedance 26,
the impedance of the bus 16 is equal to the reference impedance 26,
the impedance of the bus 16 is higher than the reference impedance 26;
one solution is to send a signal made up of a long voltage square-wave followed by a short voltage pulse.

Thus, in step E2, the voltage signal sent is made up of a long voltage square-wave followed by a short voltage pulse. The long voltage square-wave is used to determine whether the impedance of the bus 16 is lower than the reference impedance 26 and to calculate its value in this case. The short voltage pulse is used to determine whether the impedance of the bus 16 is higher than or equal to the reference impedance 26 and to calculate its value in this case.

In step E3, measuring, using the measuring means 22 of the first component 12, a reflected voltage signal 32 coming from the bus 16 therefore corresponds to a sequence composed of a response to the voltage square-wave according to the example of FIG. 2 and a response to the voltage pulse according to the example of FIG. 3.

Step E4 of storing the measurement in the memory 36 can allow a more in-depth analysis of the measurements or a subsequent analysis of the measurements.

Step E5 of analyzing the measurement in order to determine whether or not the impedance of the bus 16 is acceptable can be carried out in multiple ways.

The simplest way is to determine a voltage threshold value for measuring the reflected signal 32. For example, the criterion for determining whether the impedance of the bus 16 is acceptable could be as follows:
the response signal for the voltage square-wave must have a voltage higher than a first threshold voltage, and
the response signal for the voltage pulse must have a voltage lower than a second threshold voltage.

If one of the above two conditions is not satisfied, then the bus 16 or the entire electronic circuit is reported as not meeting the criterion. For example, a diagnosis is returned to the operator or the control unit in an embedded application.

A more complex way of determining whether the impedance of the bus 16 is acceptable is to calculate the value of the impedance of the bus 16 and compare it with a range of impedance values that are considered acceptable.

Analysis of the impedance measurement also allows capacitive behavior to be detected.

In some cases, the electronic track corresponding to the bus 16 does not have the same characteristic all the way along. This is because, in a printed circuit, for example, the tracks are not monotonous, in particular because of layer changes.

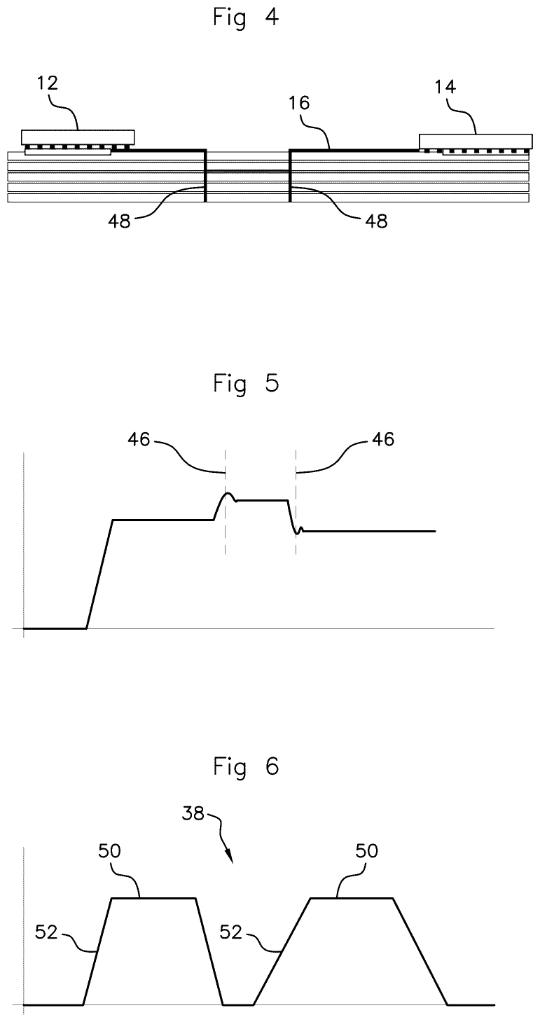

FIG. 4 shows such a printed circuit. To analyze the routing more finely, it is possible to record the discontinuities in the memory 36 of the first component 12. In this case, multiple measurement points are produced, for example by means of an acquisition by the analog-to-digital converter over a longer period.

FIG. 5 shows an example of voltage measurement carried out within the printed circuit of FIG. 4 by the measuring means 22. The measurement can be used to detect impedance breaks along the track, which are indicated by discontinuities 46 in the voltage measurement carried out. Impedance breaks are due to vias 48 along the track of the bus 16. Thus, the detection of impedance breaks makes it possible to determine that the impedance of the bus 16 is not acceptable and to reject the printed circuit.

As with a single sampling point, the transmission of a long voltage square-wave followed by the sending of a short pulse are strung together to cover all possible deviations and provide better diagnosis.

According to an improvement of the invention, the method further comprises a step of:
E6: determining the maximum operating frequency of the bus according to the gradient of the square-wave or pulse beyond which the impedance is degraded.

This is because, by adapting the rise time of the voltage square-wave or pulse, it is also possible to determine the frequency, close to the target frequency, to which the electronic circuit is best suited and thus to modify the operating speed of the bus 16 accordingly. Step E6 is relevant in particular in the context of network cards having, for example, an expansion bus according to the PCI Express, Peripheral Component Interconnect Express, standard.

FIG. 6 shows an example of a transmitted wave 38 on the bus 16 made up of a string of voltage pulses 50 having edges 52 with different rise times.

For example if a pulse with a rise time of 200 ps gives good results in terms of impedance and the impedance degrades by decreasing the rise time, then the maximum speed of the bus will be set to 1.75 GHz by virtue of the following relationship linking frequency F to rise time T:F=0.35/T.

If the analysis carried out in step E5 has identified that the impedance of the bus is lower than the theoretical impedance of the bus, that is to say the target impedance, to within a tolerance range, the method of the invention can further comprise the following step:
E7: connecting an additional impedance in series within the first component 12.

According to an improvement, the method can further comprise the following step:
E8: within the second component 14, connecting a variable impedance in parallel with the reference resistor 26 and matching the variable impedance to cancel the reflected wave on the bus 16.

The invention has many advantages, including:
rapid diagnosis;
possible activation on each printed circuit;
fine diagnosis.

### Key:

10 electronic circuit
12 first component
14 second component
16 bus
18 first functional assembly
20 transmitting means
22 measuring means
24 second functional assembly
26 reference impedance
28 switching means
30 voltage signal
32 reflected voltage signal
34 logic unit
36 memory
38 transmitted wave
40 measured wave when the impedance of the bus is lower than the reference impedance
42 measured wave when the impedance of the bus is equal to the reference impedance
44 measured wave when the impedance of the bus is higher than the reference impedance
46 discontinuity
48 vias
50 pulse
52 edge

1. An impedance checking method implemented in an electronic circuit (10) having a first component (12), a second component (14) and an electronic bus (16) capable of setting up a communication between the first component (12) and the second component (14),
the first component (12) comprising:
transmitting means (20) for transmitting a voltage, and
measuring means (22) for measuring a voltage;
the second component (14) having:
a reference impedance (26) equal to the theoretical impedance of the bus (16), and
switching means (28) having a connected state in which the reference impedance (26) is connected to the bus (16) and a disconnected state in which the reference impedance (26) is disconnected from the bus (16),
the method being characterized in that it comprises the following steps:
E1: within the second component (14), putting the switching means (28) into the connected state so as to connect the reference impedance (26) to the bus (16);
E2: sending a voltage signal (30) on the bus (16) using the transmitting means (20) of the first component (12),
E3: measuring, using the measuring means (22) of the first component (12), a reflected voltage signal (32) coming from the bus (16).

2. The impedance checking method as claimed in claim 1, characterized in that when the first component (12) further has a memory (36), the method further comprises a step E4 of storing the measurement in the memory (36).

3. The impedance checking method as claimed in claim 1, characterized in that it further comprises the following step:
E5: analyzing the measurement carried out in step E3 according to at least one predefined criterion in order to determine whether or not the impedance of the bus is acceptable.

4. The impedance checking method as claimed in claim 3, characterized in that the predetermined criterion has at least one voltage threshold value for the measurement.

5. The impedance checking method as claimed in claim 1, characterized in that in step E2, the voltage signal (30) sent is made up of a long voltage square-wave followed by a short voltage pulse.

6. The impedance checking method as claimed in claim 1, characterized in that in step E2, the voltage signal (30) sent is made up of multiple short voltage pulses having multiple voltage rise gradient steepnesses and in that it further comprises a step of:
E6: determining the maximum operating frequency of the bus according to the steepness beyond which the impedance is degraded.

7. The impedance checking method as claimed in claim 1, characterized in that it is implemented in an automated manner by an embedded system within the electronic circuit (10).

8. The impedance checking method as claimed in claim 7, characterized in that when the analysis carried out in step E5 has identified that the impedance of the bus is lower than the theoretical impedance of the bus to within a tolerance range, it further comprises the following step:
E7: connecting an additional impedance in series within the first component (12).

9. The impedance checking method as claimed in claim 1, characterized in that it further comprises the following step:
E8: within the second component (14), connecting a variable impedance in parallel with the reference resistor (26) and matching the variable impedance to cancel the reflected wave on the bus (16).

10. An electronic circuit (10) having a first component (12), a second component (14) and an electronic bus (16) capable of setting up a communication between the first component (12) and the second component (14),
the first component (12) comprising:
transmitting means (20) for transmitting a voltage, and
measuring means (22) for measuring a voltage;
the second component (14) having:
a reference impedance (26) equal to the theoretical impedance of the bus (16), and
switching means (28) having a connected state in which the reference impedance (26) is connected to the bus (16) and a disconnected state in which the reference impedance (26) is disconnected from the bus (16),
the electronic circuit (10) being characterized in that it further has a nominal state, a test state in which:
the transmitting means (20) are configured to send a predefined voltage signal (30) on the bus,
the switching means (28) are configured in the connected state, and
the measuring means (22) are configured to measure a reflected voltage signal (32) coming from the bus.

11. The electronic circuit (10) as claimed in claim 10, characterized in that the first component (12) is a microcontroller.

12. The electronic circuit (10) as claimed in claim 10, characterized in that the second component (14) is a transceiver or a network switch.

13. The electronic circuit (10) as claimed in claim 10, characterized in that the measuring means (22) have an analog-to-digital converter or analog comparison means.
